(19) United States
(12) Patent Application Publication
(10) Pub. No.: US 2026/0221162 A1
(43) Pub. Date: Jul. 30, 2026

(54) DISAGGREGATED CACHES FOR PROCESSOR CORES

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 19/038,623

(22) Filed: Jan. 27, 2025

(51) Int. Cl. G11C 5/06; H01L 25/07; H10B 80/00

(52) U.S. Cl. CPC G11C 5/06; H10B 80/00; H10W 90/00; H10W 90/297

(57) ABSTRACT

A structure is disclosed. The structure can include a first processor core, first one or more wiring layers, second one or more wiring layers, and a first cache chiplet. The first one or more wiring layers can be disposed vertically below the first processor core, with wires of the first one or more wiring layers having a first average wire width. The second one or more wiring layers can be disposed vertically below the first one or more wiring layers, with wires of the second one or more wiring layers having a second average wire width that is larger than the first average wire width. The first cache chiplet can be disposed vertically below the first one or more wiring layers and at least partially embedded within the second one or more wiring layer. The first cache chiplet can be hybrid bonded to the first one or more wiring layers.

### BACKGROUND

### Field

This disclosure relates to semiconductor device structures and methods. In particular, some embodiments are directed to integration and bonding of cache memory to processor dies.

### Description of Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Cache memory can enhance microprocessor performance by providing faster access to frequently used data. Traditionally, cache memory is organized into levels, with the fastest level being closest to the processing unit. The proximity of the fastest level offers rapid communication, but the fastest level cache is usually limited in size due to space constraints. Though larger cache levels may be utilized to improve performance, they are typically disposed farther to a processor core or exist as a separate chip, resulting in longer communication latency with the processor core. As such, it may be desirable to find a cache memory structure that improves cache capacity and speed.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1 illustrates top schematic views of a processor die that includes a plurality of processor cores and multiple cache levels.

FIG. 2A illustrates a side schematic sectional view of a bonded structure that includes a processor die and disaggregated caches according to some embodiments of the present disclosure.

FIG. 2B illustrates a side schematic sectional view of a bonded structure that includes a processor die and disaggregated caches according to some embodiments of the present disclosure.

FIG. 3 illustrates a side schematic sectional view of a bonded structure that includes a processor die and disaggregated caches according to some embodiments of the present disclosure.

FIG. 4A illustrates a side schematic sectional view of a bonded structure that includes a processor die and disaggregated caches according to some embodiments of the present disclosure.

FIG. 4B illustrates a side schematic sectional view of a bonded structure that includes a processor die and disaggregated caches according to some embodiments of the present disclosure.

FIG. 4C illustrates a side schematic sectional view of a bonded structure that includes a processor die and disaggregated caches according to some embodiments of the present disclosure.

FIG. 4D illustrates a side schematic sectional view of a bonded structure that includes a processor die and disaggregated caches according to some embodiments of the present disclosure.

FIGS. 5A-1 or 5A-2, 5B, and 5C illustrate an example process for forming a structure, such as a bonded structure, according to some embodiments.

FIGS. 6A and 6B illustrate an example process for forming a structure, such as a bonded structure, according to some embodiments.

FIGS. 7A, 7B, and 7C illustrate an example process for forming a structure, such as a bonded structure, according to some embodiments.

FIGS. 8A and 8B schematically illustrate cross-sectional side views of two elements prior to and after, respectively, a process for forming a directly bonded structure, and more particularly a hybrid bonded structure, according to some embodiments.

### SUMMARY

The systems, methods, and devices described herein each have several aspects, no single one of which is solely responsible for its desirable attributes. Without limiting the scope of this disclosure, several non-limiting features will now be described briefly.

In some aspects, the techniques described herein relate to a structure including: a first processor core; first one or more wiring layers disposed vertically below the first processor core, wires of the first one or more wiring layers having a first average wire width; second one or more wiring layers disposed vertically below the first one or more wiring layers, wires of the second one or more wiring layers having a second average wire width that is larger than the first average wire width; and a first cache chiplet for the first processor core, the first cache chiplet disposed vertically below the first one or more wiring layers and at least partially embedded within the second one or more wiring layers, wherein the first cache chiplet is hybrid bonded to the first one or more wiring layers.

In some aspects, the techniques described herein relate to a structure, wherein the first cache chiplet and the first processor core communicate with each other through the first one or more wiring layers.

In some aspects, the techniques described herein relate to a structure, wherein the first cache chiplet is a level one (L1) cache for the first processor core.

In some aspects, the techniques described herein relate to a structure, further including a first on-chip cache disposed laterally to the first processor core, wherein the first on-chip cache and the first processor core form a portion of a processor die.

In some aspects, the techniques described herein relate to a structure, wherein a storage capacity of the first on-chip cache is larger than a storage capacity of the first cache chiplet.

In some aspects, the techniques described herein relate to a structure, wherein the first cache chiplet is an off-chip cache to the processor die.

In some aspects, the techniques described herein relate to a structure, wherein the first cache chiplet is a level one (L1) cache for the first processor core, and the first on-chip cache is a level two (L2) cache for the first processor core.

In some aspects, the techniques described herein relate to a structure, wherein the first cache chiplet is a level two (L2) cache for the first processor core, and the first on-chip cache is a level one (L1) cache for the first processor core.

In some aspects, the techniques described herein relate to a structure, wherein the first on-chip cache and the first processor core communicate with each other through the first one or more wiring layers.

In some aspects, the techniques described herein relate to a structure, wherein the processor die includes the first on-chip cache, the first processor core, a second processor core, and a second on-chip cache, and wherein the second processor core and the second on-chip cache communicate with each other through the first one or more wiring layers.

In some aspects, the techniques described herein relate to a structure, wherein the first processor core and the second processor core communicate with each other through the second one or more wiring layers.

In some aspects, the techniques described herein relate to a structure, further including: a second cache chiplet that is (i) disposed vertically below the first one or more wiring layers, (ii) at least partially embedded within the second one or more wiring layers, and (iii) hybrid bonded to the first one or more wiring layers, wherein the second cache chiplet and the second processor core communicate with each other through the first one or more wiring layers.

In some aspects, the techniques described herein relate to a structure, wherein the second cache chiplet is a level one (L1) cache for the second processor core, and the second on-chip cache is a level two (L2) cache for the second processor core.

In some aspects, the techniques described herein relate to a structure, wherein the second cache chiplet is a level two (L2) cache for the second processor core, and the second on-chip cache is a level one (L1) cache for the second processor core.

In some aspects, the techniques described herein relate to a structure, further including a third on-chip cache, wherein the second cache chiplet is a level one (L1) cache for the second processor core, the second on-chip cache is a level two (L2) cache for the second processor core, and the third on-chip cache is a level three (L3) cache for the first processor core and the second processor core.

In some aspects, the techniques described herein relate to a structure, wherein the third on-chip cache communicates with the first processor core and the second processor core through the second one or more wiring layers.

In some aspects, the techniques described herein relate to a structure, wherein the processor die includes the first on-chip cache, the first processor core, a second processor core, and a substrate, and wherein the first on-chip cache, the first processor core, and the second processor core are disposed vertically below the substrate.

In some aspects, the techniques described herein relate to a structure, further including a second cache chiplet and a third cache chiplet, wherein the second cache chiplet is a level one (L1) or a level two (L2) cache for the second processor core, and the third cache chiplet is a level three (L3) cache for the first processor core and the second processor core.

In some aspects, the techniques described herein relate to a structure, wherein the third cache chiplet is disposed vertically above the substrate.

In some aspects, the techniques described herein relate to a structure, wherein the processor die includes a plurality of through substrate vias, wherein the third cache chiplet communicates with the first processor core and the second processor core through the plurality of through substrate vias.

In some aspects, the techniques described herein relate to a structure including: a processor die that includes a first processor core and a first on-chip cache; and a first cache chiplet dedicated for the first processor core, the first cache chiplet disposed vertically below the first processor core and the first on-chip cache, wherein: the first cache chiplet is hybrid bonded to the processor die; and a storage capacity of the first cache chiplet is smaller than a storage capacity of the first on-chip cache.

In some aspects, the techniques described herein relate to a structure, wherein the first on-chip cache is a level two (L2) cache for the first processor core, and the first cache chiplet is a level one (L1) cache for the first processor core.

In some aspects, the techniques described herein relate to a structure, wherein the first cache chiplet is an off-chip cache to the processor die.

In some aspects, the techniques described herein relate to a structure, wherein the processor die includes a second on-chip cache, and wherein the first cache chiplet is a level one (L1) cache for the first processor core, the first on-chip cache is a level two (L2) cache for the first processor core, and the second on-chip cache is a level three (L3) cache for the first processor core.

In some aspects, the techniques described herein relate to a structure, wherein the processor die includes a substrate, and wherein the first processor core, the first on-chip cache, and the second on-chip cache are disposed vertically below the substrate.

In some aspects, the techniques described herein relate to a structure, further including a second cache chiplet, wherein the second cache chiplet is disposed vertically above the substrate.

In some aspects, the techniques described herein relate to a structure, wherein the second cache chiplet is another level three (L3) cache for the first processor core.

In some aspects, the techniques described herein relate to a structure, wherein the processor die includes a plurality of through substrate vias, and wherein the second cache chiplet communicates with the first processor core through the plurality of through substrate vias.

In some aspects, the techniques described herein relate to a structure, further including a cooling semiconductor die that is disposed vertically above the substrate.

In some aspects, the techniques described herein relate to a structure, wherein the first cache chiplet is reconstituted.

In some aspects, the techniques described herein relate to a method for forming a bonded structure, the method including: forming at least a processor core and an on-chip cache on a first side of a substrate; forming first one or more wiring layers on a first side of the processor core and the on-chip cache; and bonding a cache chiplet to a first side of the first one or more wiring layers, wherein the cache chiplet communicates with the processor core through the first one or more wiring layers as an off-chip cache that is dedicated to the processor core.

In some aspects, the techniques described herein relate to a method, wherein bonding the cache chiplet to the first side of the first one or more wiring layers includes hybrid bonding the cache chiplet to the first side of the first one or more wiring layers.

In some aspects, the techniques described herein relate to a method, wherein the cache chiplet is carried by a carrier substrate.

In some aspects, the techniques described herein relate to a method, wherein the cache chiplet is at least partially embedded within second one or more wiring layers that are deposited vertically above the carrier substrate.

In some aspects, the techniques described herein relate to a method, further including removing the carrier substrate without removing the second one or more wiring layers.

In some aspects, the techniques described herein relate to a method, further including forming second one or more wiring layers vertically below the first one or more wiring layers, wherein the cache chiplet is at least partially embedded within the second one or more wiring layers.

In some aspects, the techniques described herein relate to a method, further including hybrid bonding second one or more wiring layers to the cache chiplet or the first one or more wiring layers, wherein the second one or more wiring layers are disposed vertically above a carrier substrate.

In some aspects, the techniques described herein relate to a method, further including removing the carrier substrate.

In some aspects, the techniques described herein relate to a method, wherein the cache chiplet is a level one (L1) cache or a level two (L2) cache.

Various combinations of the above and below recited features, embodiments, and aspects are also disclosed and contemplated by the present disclosure.

Additional embodiments of the disclosure are described below in reference to the appended claims, which may serve as an additional summary of the disclosure.

### DETAILED DESCRIPTION

Although several embodiments, examples, and illustrations are disclosed below, it will be understood by those of ordinary skill in the art that the disclosure described herein extends beyond the specifically disclosed embodiments, examples, and illustrations and includes other uses of the disclosure and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the disclosure. In addition, embodiments can comprise several novel features. No single feature is solely responsible for its desirable attributes or is essential to practicing the disclosure herein described.

As the demand for high-performance computing increases, existing memory architecture including on-chip memory like cache architectures for a processor die may face limitations in terms of speed, data throughput, and/or thermal performance. Some embodiments disclosed herein nevertheless accomplish increased data access speed or efficiency, increased cache capacity, and/or reduced processor die size (or larger processor size for the same footprint) by disaggregating some cache(s) from a processor die (e.g., moving some cache from within the processor die to without the processor die) and bonding (e.g., hybrid bonding) disaggregated cache(s) to the processor die. As used herein, disaggregated cache can refer to a cache architecture where some cache memory (e.g., L1 cache) is separated from a processor die and disposed in a different physical location (e.g., outside the processor die), rather than being integrated within the processor die.

Cache memory refers to a specialized form of high-speed memory that enhances the performance of a computing system or a processor die by storing frequently accessed data and instructions. Cache memory is typically categorized into levels, such as L1, L2, and L3, based on proximity and accessibility to the microprocessor. L1 cache, being the closest to the processor, offers fastest access but limited capacity. L2 cache provides a balance between speed and size, while L3 cache, though slower, offers greater storage capacity. The L1, L2 and L3 caches work together to optimize data retrieval and processing efficiency in computing systems.

Modern computing systems generally demand high-speed data processing and efficient memory management to support complex applications, such as artificial intelligence and machine learning. Cache memory can play a role in bridging the speed gap between the processor and main memory. Traditional cache architectures, including L1, L2, and L3 caches, are integrated within the processor chip to provide faster access (e.g., compared with accessing main memory) to frequently used data. However, existing cache architectures may face several limitations.

First, as noted above, although L3 cache can be deployed to compensate for the limited size of L1 or L2 cache, L3 cache is typically disposed farther to a processor core or even can exist on a die separate from a processor die that includes the processor core. As such, communication latency between a processor core and caches is high when accessing larger datasets that are stored in L3 cache.

Second, existing caches dedicated (e.g., L1 or L2 cache) to a processor core (e.g. on chip memory) are typically spaced laterally from the processor core on the same die or chip. The lateral distance between a cache dedicated to a processor core and the processor core may pose a bottleneck on communication latency. For example, a typical distance between L1 cache and a processor core may be around 10 micrometers (μm) to 1000 μm, which can impose limitation on data transfer speed between the L1 cache and the processor core.

Additionally, the limited physical space available for deploying on-chip caches may restrict their ability to handle large datasets, leading to performance bottlenecks in data-intensive applications. For example, integration of L1, L2, and L3 caches within a processor die may confine sizes of the L1, L2, and/or L3 caches due to space constraints within the processor die, which can limit their capacity to store data. Such limitation may necessitate frequent data transfers between the processor die and external memory, increasing latency and reducing overall system performance. Further, the hierarchical nature of traditional cache systems may result in increased complexity and power consumption, as data may traverse multiple cache levels (e.g., traverse from L3 cache to L2 cache) before reaching a processor core.

To address at least a portion of the aforementioned problems, some embodiments herein disclose structures and techniques that disaggregate some cache(s) (e.g., L1 and/or L2 cache) from a processor die to allow a larger cache size for a disaggregated cache that is disposed outside the processor die. In some embodiments, instead of being disposed inside a processor die as an on-chip cache, a L1 or a L2 cache may be disposed outside the processor die as an off-chip cache, thereby allowing the L1 or the L2 cache to be larger in size without being constrained by limited space within the processor die, without sacrificing the latency requirements.

In some embodiments, a disaggregated cache (e.g., a L1 cache) can be disposed vertically below a processor core. The L1 cache can be hybrid bonded to one or more local wiring layers that are below the processor core. The L1 cache can communicate with the processor core through the one or more local wiring layers, and can serve as a dedicated cache for the processor core. By hybrid bonding the L1 cache to the one or more local wiring layers, the L1 cache may communicate with the processor core through the one or more local wiring layers with a vertical distance that can be less than a few micrometers (e.g., 2 μm, between 1 μm to 10 μm, between 0.5 μm to 5 μm, between 2 μm to 50 μm, between 10 μm to 100 μm, between 15 μm to 1000 μm or the like). Compared with existing cache architectures where a L1 cache communicates with a processor core through a lateral communication path that can be around 50 μm, a disclosed structure with an off-chip L1 or L2 cache hybrid bonded to one or more local wiring layers may achieve significantly lower data latency.

As used herein, the one or more local wiring layers may be layers of a processor die that are closer to (e.g., compared to one or more intermediate and global wiring layers of a processor die) processor cores of the processor die. The one or more local wiring layers may facilitate shorter distance communication associated with the processor die, such as communication between a processor core and a cache (e.g., a L1 cache and/or a L2 cache) dedicated to the processor core. The one or more local wiring layers may include metal wires that have smaller pitch and/or wire width (e.g., compared to pitch and/or wire width of one or more intermediate and global wiring layers), allowing for high-density interconnections. The one or more local wiring layers of the processor die may be distinct from one or more intermediate and global wiring layers of the processor die. The one or more intermediate and global wiring layers may facilitate longer distance communication associated with the processor die, such as communication between various processor cores and/or between a processor core and a L3 cache. In some embodiments, an off-chip L1 cache (e.g., a L1 cache chiplet) can be hybrid bonded to and disposed vertically below the one or more local wiring layers. Further, the off-chip L1 cache can be at least partially embedded within the one or more intermediate and global wiring layers.

In some embodiments, a disclosed structure may include a disaggregated L1 cache (e.g., an off-chip L1 cache) that can be larger in size compared with on-chip L1 cache. The structure may include L2 and/or L3 cache (e.g., on-chip L2 and/or L3 caches) that are smaller in size without compromising performance of a processor die because of the increase in size of the off-chip L1 cache. Advantageously, the smaller L2 and/or L3 cache can in turn allow the processor die to be smaller in size, which can reduce cost and complexity of manufacturing the processor die.

In some embodiments, a disclosed structure may include at least a processor die and a first cache chiplet. The processor die includes a processor core and an on-chip cache. The first cache chiplet (e.g., an off-chip L1 or L2 cache) can be dedicated for the processor core, and can be disposed vertically below the processor core and the on-chip cache. The first cache chiplet is hybrid bonded to the processor die. A storage capacity of the first cache chiplet (e.g., a L1 cache) is smaller than a storage capacity of the on-chip cache (e.g., a L2 or L3 cache). More specifically, the processor die can include a substrate, and the processor core, the on-chip cache, and the first cache chiplet may be disposed vertically below the substrate. The disclosed structure may further include a second cache chiplet (e.g., a L3 cache) that is disposed vertically above the substrate. Additionally and/or alternatively, a cooling semiconductor die can be vertically disposed above the substrate.

As noted above, by disaggregating some cache(s) from a processor die, a disaggregated cache (e.g., an off-chip cache) that is disposed outside the processor die can provide larger storage capacity. For example, a disaggregated L1 cache can provide larger storage capacity compared with an on-chip L1 cache because space outside the processor die may be less constrained. By hybrid bonding the disaggregated cache vertically below the processor die, data transfer latency between a processor core of the processor die and the disaggregated cache can be reduced compared with situations where the processor core communicates with an on-chip cache through a lateral communication path. As noted above, this is because a vertical communication path between the processor core and the disaggregated cache can be much shorter (e.g., less than a few micrometers) than the lateral communication path (e.g., around or above 50 μm). The larger storage capacity provided by the disaggregated cache can also allow reduced sizes of on-chip cache(s) without incurring performance degradation resulted from decrease in overall storage capacity. The reduced sizes of on-chip cache(s) can in turn allow size of a processor die to be reduced, resulting in reduced cost and complexity of manufacturing the processor die.

Additionally, instead of hybrid bonding to one or more intermediate and global wiring layers of a processor die, a disaggregated cache can be hybrid bonded to one or more local wiring layers of the processor die that may include metal wires having smaller wire widths. In some embodiments, a disaggregated cache can be hybrid bonded to one or more intermediate wiring layers of the processor die. Advantageously, smaller wire widths associated with the one or more local (or intermediate) wiring layers may facilitate hybrid bonding between the disaggregated cache and the processor die. Further, hybrid bonding the disaggregated cache (e.g., an off-chip L1 cache) vertically below the processor die may not hinder or negatively affect routing wires in wiring layers below processor cores because space occupied by the off-chip L1 cache may be smaller (e.g., compared with space occupied by an off-chip L3 cache). Additionally and/or optionally, an off-chip L3 cache can be disposed vertically above a substrate and processor cores of a processor die to further increase cache storage capacity available for the processor cores. As noted above, a cooling semiconductor die can be also disposed above the substrate to advantageously avoid thermal issues associated with the processor die.

### Conventional Semiconductor Devices

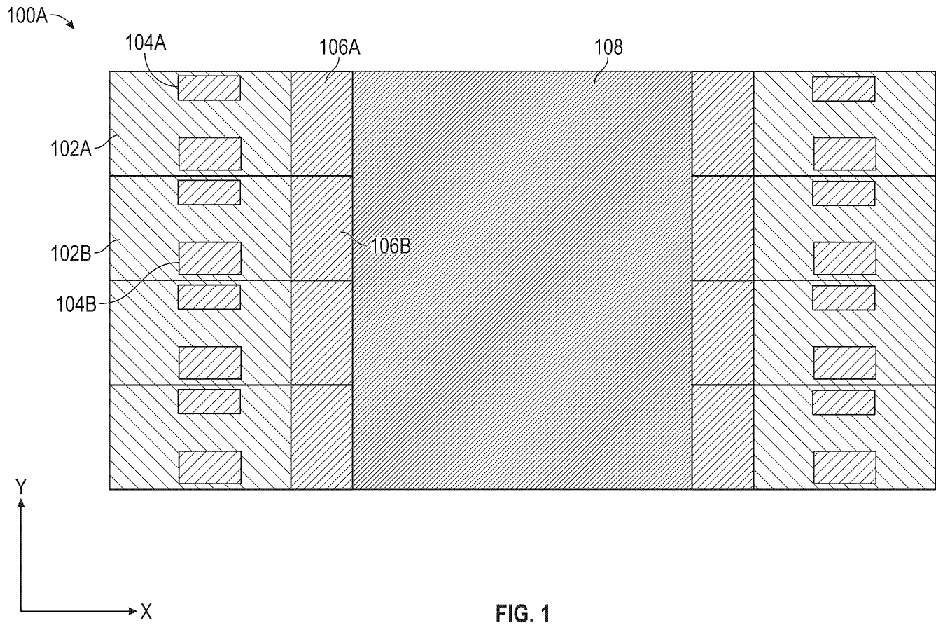

FIG. 1 illustrates top schematic views of an exemplary processor die 100A that includes a plurality of processor cores and multiple cache levels. As shown in FIG. 1, the processor die 100A includes at least a processor core 102A, a processor core 102B, and a L3 cache 108. The processor core 102A includes at least a L1 cache 104A and a L2 cache 106A. The processor core 102B includes at least a L1 cache 104B and a L2 cache 106B. The L1 cache 104A, the L2 cache 106A, the L1 cache 104B, the L2 cache 106B, and the L3 cache 108 can be on-chip caches to the processor die 100A. FIG. 1 depicts just one exemplary layout of a processor die 100A that includes several processor cores and cache memory L1, L2, and L3, neighboring or around each processor core. Any another suitable processor die layout of processor core or cache distribution, orientation, size or may be possible. Although cache controllers are not shown, the cache controllers can also be designed and implemented into the processor die 100A.

In some embodiments, the L1 cache 104A and the L2 cache 106A can be dedicated to (e.g., the processor core 102B may not access the L1 cache 104A or the L2 cache 106A) the processor core 102A. The L1 cache 104B and the L2 cache 106B can be dedicated to (e.g., the processor core 102A may not access the L1 cache 104B or the L2 cache 106B) the processor core 102B. The L3 cache 108 can be shared among the processor core 102A and the processor core 102B. In some embodiments, L2 cache may be adjacent to the processor core (e.g. outside of the footprint of the processor core) and can be shared by several processor cores. In some embodiments, L3 cache may not be on the processor die (e.g. off-chip L3 cache).

In some embodiments, the processor die 100A can be a GPU (graphics processing unit) die, a CPU (central processing unit) die, a NPU (neural networking processing unit) die, a TPU (tensor processing unit) die, a network switch, an FPGA (field programmable grid array), an ASIC (application specific integrated circuit), or the like (e.g., any suitable processing die or chip). The processor core 102A, the processor core 102B, the L1 cache 104A, the L2 cache 106A, L1 cache 104B, the L2 cache 106B, and the L3 cache 108 may be laterally spaced from each other. For example, the processor core 102A, the L2 cache 106A, and the L3 cache 108 may be laterally spaced from each other, with the processor core 102A being around an edge of the processor die 100A, the L2 cache 106A being between the processor core 102A and the L3 cache 108, and the L3 cache 108 being at or near a center of the processor die 100A. As another example, the processor core 102B, the L2 cache 106B, and the L3 cache 108 may be laterally spaced from each other, with the processor core 102B being around an edge of the processor die 100A, the L2 cache 106B being between the processor core 102B and the L3 cache 108, and the L3 cache 108 being at or near a center of the processor die 100A.

In some embodiments, the L1 cache 104A is closer to the processor core 102A than the L2 cache 106A and the L3 cache 108. The L1 cache 104B is closer to the processor core 102B than the L2 cache 106B and the L3 cache 108. In some embodiments, L1 cache is designed as a part of the processor core 102A and/or 102B. The L1 cache 104A can provide the processor core 102A rapid access to frequently used data and instructions. The L1 cache 104B can provide the processor core 102B rapid access to frequently used data and instructions. Examples of L1 cache include instruction cache, data cache, etc.

In some embodiments, the L2 cache 106A is farther to the processor core 102A compared with the L1 cache 104A, and is closer to the processor core 102A compared with the L3 cache 108. The L2 cache 106A can offer the processor core 102A a balance between access speed and storage capacity by serving as an intermediary storage layer to hold data that may not be immediately needed by the processor core 102A. The L2 cache 106B is farther to the processor core 102B compared with the L1 cache 104B, and is closer to the processor core 102B compared with the L3 cache 108. The L2 cache 106B can offer the processor core 102B a balance between access speed and storage capacity by serving as an intermediary storage layer to hold data that may not be immediately needed by the processor core 102B.

In some embodiments, the L3 cache 108 may be at or near a center of the processor die 100A, and may be shared by the processor core 102A and the processor core 102B. The L3 cache 108 can provide a larger storage capacity, accommodating data that is less frequently accessed by the processor core 102A and the processor core 102B but still benefits from being closer to the processor than a main memory (not shown in FIG. 1).

In the processor die 100A, although the L3 cache 108 can be deployed to compensate for the limited size of L1 or L2 cache (e.g., the L1 cache 104A, the L2 cache 106A), the L3 cache 108 is disposed farther to the processor core 102A and the processor core 102B. As such, communication latency between the processor cores 102A and 102B and caches may increase when accessing larger datasets that are stored in the L3 cache 108. Additionally, the lateral distance between a cache dedicated to a processor core and the processor core may pose a bottleneck on communication latency. For example, a distance between the L1 cache 104A and the processor core 102A may be around 2 μm, between 1 μm to 10 μm, between 0.5 μm to 5 μm, between 2 μm to 50 μm, between 10 μm to 100 μm, between 15 μm to 1000 μm, or the like, which can impose limitation on data transfer speed between the L1 cache 104A and the processor core 102A. Further, the limited physical space available for deploying on-chip caches may restrict their ability to handle large datasets, leading to performance bottlenecks in data-intensive applications. For example, integrating the L1 cache 104A, the L1 cache 104B, the L2 cache 106A, the L2 cache 106B, and the L3 cache 108 within the processor die 100A may confine sizes of these caches due to space constraints imposed on the processor die 100A, which can limit capacity of these caches to store data. Such limitation may necessitate frequent data transfers between the processor die and external memory, increasing latency and reducing overall system performance.

As noted above, some implementations disclosed herein can accomplish increased data access speed or efficiency, increased cache capacity, and/or reduced processor die size by disaggregating some cache(s) from a processor die (e.g., moving some cache from within the processor die 100A to without the processor die 100A) and bonding (e.g., hybrid bonding) disaggregated cache(s) to the processor die. By disaggregating a cache from within a processor die, a larger cache size can be advantageously obtained for a disaggregated cache that is disposed outside the processor die. The disaggregated cache may communicate with a processor core through a vertical communication path that can be comparable or even significantly shorter than a lateral communication path between a processor core and a cache (e.g., the processor core 102A and the L1 cache 104A) in the processor die 100A providing significantly larger capacity with similar or even better latency.

### Example Bonded Structures

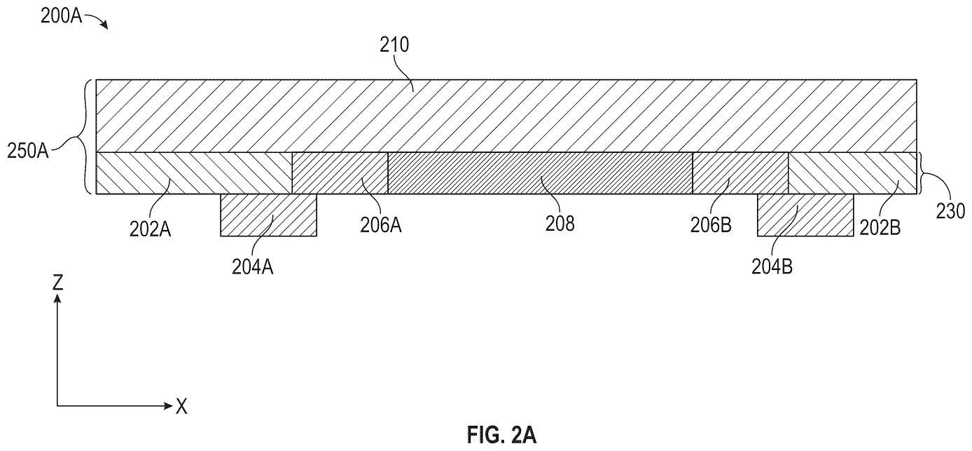

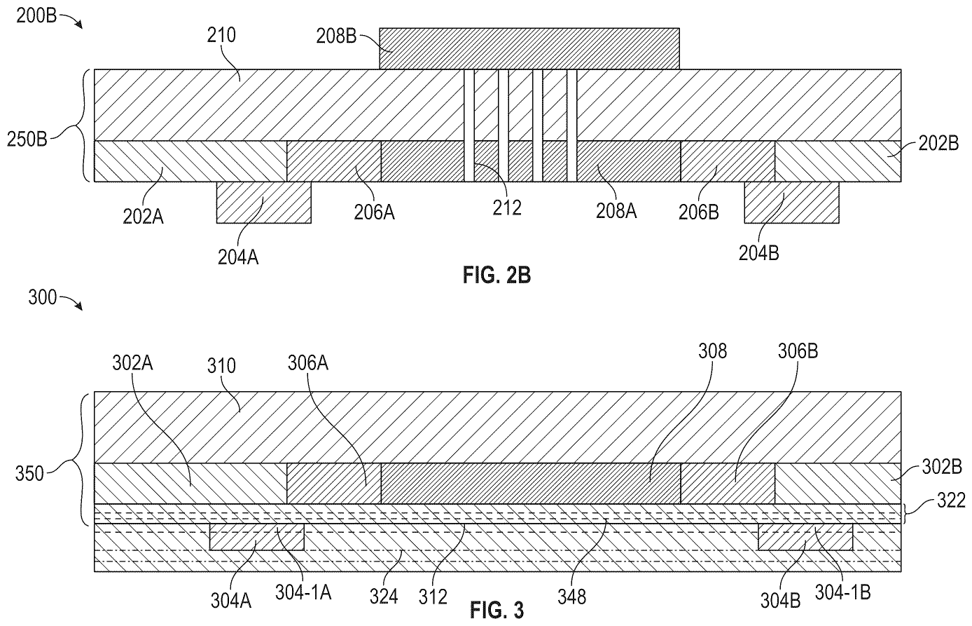

FIG. 2A illustrates a side schematic sectional view of a bonded structure 200A that includes a processor die and disaggregated caches according to some embodiments of the present disclosure. The bonded structure 200A includes at least a processor die 250A, a L1 cache 204A, and a L1 cache 204B. The processor die 250A includes a substrate 210, a processor core 202A, a L2 cache 206A, a L3 cache 208, a L2 cache 206B, and a processor core 202B. In some embodiments, the L1 cache 204A and the L2 cache 206A can be accessed by and/or dedicated to the processor core 202A. The L1 cache 204B and the L2 cache 206B can be accessed by and/or dedicated to the processor core 202B. The L3 cache 208 can be shared among the processor core 202A and the processor core 202B.

As shown in FIG. 2A, the processor core 202A, the L2 cache 206A, the L3 cache 208, the L2 cache 206B, and the processor core 202B are formed toward a bottom side of the substrate 210 and/or disposed below the substrate 210. For example, processor core and on-chip cache are formed/fabricated to make (or define) the active side of the substrate. Instead of integrated within the processor die 250A, the L1 cache 204A and the L1 cache 204B are disaggregated from the processor die 250A, and are disposed vertically below the processor core 202A and the processor core 202B, respectively. As such, the L2 cache 206A, the L3 cache 208, and the L2 cache 206B can be on-chip caches to the processor die 250A (e.g., the L2 cache 206B being an on-chip cache to the processor core 202B). The L1 cache 204A and the L1 cache 204B can be off-chip caches to the processor die 250A. In some embodiments, L2 cache is disaggregated from the processor die 250A, and/or disposed below the substrate 210 (e.g. using hybrid bonding). and the L1 cache and/or L3 cache can be on-chip caches to the processor die 250A. In some other embodiments, both L1 and L2 cache is disaggregated from the processor die 250A, and/or disposed below the substrate 210 (e.g. using hybrid bonding).

In some embodiments, the processor die 250A can be a GPU die, a CPU die, a NPU die, a TPU die, a network switch, an FPGA, an ASIC, or the like. Although FIG. 2A illustrates that the processor die 250A includes the processor core 202A and the processor core 202B, it should be noted that the processor die 250A may include other number (e.g., three, four, eight, twelve, sixteen) of processor cores. As shown in FIG. 2A, the processor core 202A, the L2 cache 206A, the L3 cache 208, the L2 cache 206B, and the processor core 202B can be laterally spaced from each other (e.g., similar to the implementation of FIG. 1). In contrast to the implementation of FIG. 1, the L1 cache 204A and the L1 cache 204B are disposed vertically below the processor core 202A, the L2 cache 206A, the L3 cache 208, the L2 cache 206B, and the processor core 202B.

In some embodiments, the substrate 210 can be a semiconductor substrate (e.g., an undoped semiconductor material, a silicon substrate including base silicon material, or the like) in which active circuitry (e.g., processor cores such as the processor core 202A and the processor core 202B, and on-chip caches such as L3 cache 208, L2 cache 206A, and L2 cache 206B) can be doped, formed or fabricated via conventional front end process. As such, the active circuitry can be disposed within active regions 230 (e.g., the processor core 202A can be disposed within a first active region of the active regions 230, the L3 cache 208 can be disposed within a second active region of the active regions 230, or the like) of the processor die 250A. Additionally and/or optionally, wiring layers (e.g., wiring layers 322 and/or wiring layers 324 that will be described below with reference to FIG. 3) can be formed on top of the active regions 230. In some embodiments, through-substrate vias (TSVs) can be disposed in the substrate 210 to connect to terminals on various sides of the substrate 210, which in turn can be connected to another die, interposer or a system board (not shown in FIG. 2A) or other components within a larger electronic system. The substrate 210 may provide a solid foundation for the processor die 250A, allowing components (e.g., the L2 cache 206A and the L3 cache 208) to be disposed, patterned, or formed within. As noted above, the processor core 202A, the L2 cache 206A, the L3 cache 208, the L2 cache 206B, and the processor core 202B can be formed or fabricated on or within the substrate 210. As shown in FIG. 2A, the processor core 202A, the L2 cache 206A, the L3 cache 208, the L2 cache 206B, and the processor core 202B can be disposed on a first side (e.g., a front side) of the processor die 250A. In some embodiments, a cooling semiconductor die (not shown in FIG. 2A) can be disposed on a second side (e.g., a back side) of the processor die 250A that is opposite to the first side. As such, the substrate 210 may aid in thermal management and efficiently conducting heat away from the processor core 202A and the processor core 202B, thereby preventing overheating and thermal issues associated with the bonded structure 200A.

In some embodiments, the processor core 202A and/or the processor core 202B can execute instructions to perform computational tasks. For example, the processor core 202A and/or the processor core 202B may support various instruction sets to perform a wide variety of operations, from basic arithmetic to complex algorithmic computations for diverse applications, such as AI and machine learning related applications. The processor core 202A can include communication interfaces for communication with other cores (e.g., the processor core 202B) and caches of the processor die 250A.

As shown in FIG. 2A, the L2 cache 206A can be laterally spaced from (e.g. adjacent to) the processor core 202A. The L2 cache 206A can be integrated into the processor die 250A as an on-chip cache. The L2 cache 206A can be dedicated to the processor core 202A, and may provide the processor core 202A a storage capacity that is smaller than the L3 cache 208 with faster access time compared with the L3 cache 208. In some embodiments, the L2 cache may store both data and instructions for the processor core 202A, and hold data that may not be immediately accessed by the processor core 202A but is likely to be accessed soon. Similar to the relationship between the L2 cache 206A and the processor core 202A, the L2 cache 206B can be laterally spaced from the processor core 202B. The L2 cache 206B can be integrated into the processor die 250A as an on-chip cache. The L2 cache 206B can be dedicated to the processor core 202B, and may provide the processor core 202B a storage capacity that is smaller than the L3 cache 208 with faster access time compared with the L3 cache 208. In some embodiments, the L2 cache may store both data and instructions for the processor core 202B, and hold data that may not be immediately accessed by the processor core 202B but is likely to be accessed soon.

The L3 cache 208 can be shared by the processor core 202A and the processor core 202B, and can provide a larger storage capacity for data that is less frequently accessed but still benefits from being closer to the processor core 202A and the processor core 202B than a main memory (not shown in FIG. 2A). Compared with the L2 cache 206A and the L2 cache 206B, the L3 cache 208 may be slower in terms of speed. As shown in FIG. 2A, the L3 cache 208 may be integrated as an on-chip cache to the processor die 250A, and may be disposed at or near a center of the processor die 250A to be effectively shared by processor cores of the processor die 250A.

Rather than integrating into the processor die 250A and disposing the L1 cache 204A and the L1 cache 204B to be laterally spaced from the processor core 202A and the processor core 202B, the L1 cache 204A and the L1 cache 204B can be disaggregated caches (e.g., cache chiplets) that are respectively disposed vertically below the processor core 202A and the processor core 202B. The L1 cache 204A and/or the L1 cache 204B can be bonded (e.g., hybrid bonded without adhesive or an intervening layer or flip chipped or micro-bumped) to the processor die 250A. Although not shown in FIG. 2A, in some embodiments, the processor die 250A and the cache chiplets (e.g., the L1 cache 204A and the L1 cache 204B) can each have a hybrid bonding layer (e.g., a part of wiring layer(s)) disposed over the active regions 230 and the cache chiplets to enable hybrid bonding. For example, the L1 cache 204A can be hybrid bonded (e.g., dielectric-to-dielectric direct bonds and metal-to-metal direct bonds with electrical contact or electrical connection) to the processor die 250A under the processor core 202A through the hybrid bonding layer(s). As another example, the L1 cache 204A can be hybrid bonded to the processor core 202A and/or the L2 cache 206A through the hybrid bonding layer(s). In some embodiments, hybrid bonding layers of the processor die 250A and the L1 cache 204A can at least partially overlap with each other. Hybrid bonding the cache 204A to the processor die 250A may create strong mechanical and electrical connections without adhesives, ensuring robust integration, structural integrity of connections, and reliable signal transmission under small wire pitch associated with the bonded structure 200A. Although the L1 cache 204A and the L1 cache 204B are illustrated in FIG. 2A to overlap with processor cores and on-chip cache (e.g., the L1 cache 204B overlaps with the processor core 202A and the L2 cache 206A), it should be noted that in other embodiments the L1 cache 204A and/or the L1 cache 204B can be hybrid bonded only under processor cores 202A and/or 202B, only under L2 cache 206A and/or 206B, or only under L3 cache 208. The L1 cache 204A can also provide a high-speed memory storage dedicated to processor core 202A. In some embodiments, the L1 cache 204A can be designed to provide rapid access to data and instructions frequently used by the processor core 202A. In some other embodiments, L2 cache 206A and the L2 cache 206B can be disaggregated caches (e.g., cache chiplets) that are respectively disposed vertically below the processor core 202A and the processor core 202B. In such embodiments, the L2 cache 206A and/or the L2 cache 206B can be bonded (e.g., hybrid bonded without adhesive or an intervening layer or flip chipped or micro-bumped) to the processor die 250A.

As another example similar to what is noted above, the L1 cache 204B can be hybrid bonded to the processor die 250A under the processor core 202B through hybrid bonding layer(s). Hybrid bonding the cache 204B to the processor die 250A may create strong mechanical and electrical connections without adhesives, ensuring robust integration, structural integrity of connections, and reliable signal transmission associated with the bonded structure 200A. The L1 cache 204B can also provide a high-speed memory storage dedicated to processor core 202B. In some embodiments, the L1 cache 204B can be designed to provide rapid access to data and instructions frequently used by the processor core 202B. It should be noted that, although the illustrated embodiments show cache chiplets (e.g., the L1 cache 204A and the L1 cache 204B) hybrid bonded to the processor die 250A, the cache chiplets can be attached to the processor die 250A by way of solder balls in other embodiments.

By disaggregating the L1 cache 204A and the L1 cache 204B from the processor die 250A and/or hybrid bonding the L1 cache 204A and the L1 cache 204B to the processor die 250A, the bonded structure 200A can offer several advantages over the implementation of FIG. 1. First, the L1 cache 204A and the L1 cache 204B may provide larger storage capacity compared with situations where the L1 cache 204A and the L1 cache 204B are spaced laterally from the processor core 202A and the processor core 202B, because there may be more available space outside the processor die 250A to dispose the L1 cache 204A and the L1 cache 204B. Second, by hybrid bonding the disaggregated L1 cache 204A and L1 cache 204B vertically below the processor die 250A, data transfer latency between the processor core 202A or the processor core 202B and the L1 cache 204A or L1 cache 204B can be comparable or similar or even reduced (e.g., compared with data transfer latency between the processor core 102A and the L1 cache 104A that communicate with each other through a lateral communication path). As noted above, this is because a vertical communication path between the processor core 204A/B and the L1 cache 204A/B can be much shorter (e.g., less than a few micrometers, less than 2 μm, between 1 μm to 3 μm, between 0.5 μm to 4 μm, between 2 μm to 5 pm, or the like) than the lateral communication path (e.g., around or above 50 μm, between 50 μm to 100 μm, between 40 μm to 90 μm, between 60 μm to 200 μm, between 50 μm to 300 μm, between 50 μm to 500 μm, between 100 μm to 1000 μm or the like). Additionally, the larger storage capacity provided by the L1 cache 204A and the L1 cache 204B can also allow reduced sizes of on-chip cache(s) (e.g., the L2 cache 206A, the L2 cache 206B, and/or the L3 cache 208) without incurring performance degradation resulted from decrease in overall storage capacity. The reduced sizes of on-chip cache(s) can in turn advantageously allow size of the processor die 250A to be reduced, resulting in reduced cost and complexity of manufacturing the processor die 250A.

As shown in FIG. 2A, the L1 cache 204A is disposed partially under the processor core 202A and partially under the L2 cache 206A. The L1 cache 204B is disposed partially under the processor core 202B and partially under the L2 cache 206B. It should be noted that, in other embodiments, the L1 cache 204A can be disposed completely under the processor core 202A, and/or the L1 cache 204B can be disposed completely under the processor core 202B.

FIG. 2B illustrates a side schematic sectional view of a bonded structure 200B that includes a processor die and disaggregated caches according to some embodiments of the present disclosure. Unless otherwise noted, the components of FIG. 2B can be the same as or generally similar to like-numbered components of FIG. 2A. The bonded structure 200B includes at least a processor die 250B, a L1 cache 204A, a L1 cache 204B, and a L3 cache 208B. In some embodiments, the L1 cache 204A, the L1 cache 204B, and the L3 cache 208B can be cache chiplets that are hybrid bonded (e.g., dielectric-to-dielectric direct bonds and metal-to-metal direct bonds with electrical contact or electrical connection) to the processor die 250B. The processor die 250B includes a substrate 210, a processor core 202A, a L2 cache 206A, a L3 cache 208A, a L2 cache 206B, and a processor core 202B. In some embodiments, the L3 cache 208A and the L3 cache 208B can be shared among the processor core 202A and the processor core 202B. In some embodiments, L2 cache can be disaggregated and a chiplet of L2 cache can be hybrid bonded to processor die 250B comprising L1 cache and processor cores.

As shown in FIG. 2B, the substrate 210 includes vias 212 that can electrically connect cache 208B that is disposed above the substrate 210 to components (e.g., the L3 cache 208A) of the processor die 250B that are disposed below the substrate 210. In some implementations, the vias 212 can be through-substrate vias (TSVs) that traverse vertically through the substrate 210 to provide electrical connections between components (e.g., the L3 cache 208B) on a first side of the substrate 210 and components (e.g., the processor core 202A) on a second side of the substrate 210 that is opposite to the first side. By further disposing the L3 cache 208B above the substrate 210 and electrically connecting the L3 cache 208B using the vias 212, the processor core 202A and/or the processor core 202B may access larger cache storage because of the presence of the on-chip L3 cache 208A and the disaggregated L3 cache 208B to advantageously improve computational performance associated with the bonded structure 200B. In some embodiments, cache 208B can be L1 cache or L2 cache chiplet. Although not shown in FIG. 2B, the substrate 210 can further include one or more dielectric layers to provide electrical insulation and structural support. The substrate 210 can additionally and/or optionally include one or more redistribution layers (RDLs) (not shown in FIG. 2B). Additionally, a cooling semiconductor die can be disposed above the substrate 210 for thermally managing the processor die 250B (e.g., preventing overheating associated with the processor core 202A and the L2 cache 206B).

It should be noted that, in other embodiments not illustrated in FIG. 2B, the L2 cache 206A and the L1 cache 204A can be swapped (e.g., the L1 cache 204A is disposed in the processor die 250B, and the L2 cache 206A is an off-chip cache hybrid bonded to the processor die 250B), and/or the L2 cache 206B and the L1 cache 204B can be swapped (e.g., the L1 cache 204B is disposed in the processor die 250B, and the L2 cache 206B is an off-chip cache hybrid bonded to the processor die 250B).

FIG. 3 illustrates a side schematic sectional view of a bonded structure 300 that includes a processor die and disaggregated caches according to some embodiments of the present disclosure. Unless otherwise noted, the components of FIG. 3 can be the same as or generally similar to like-numbered components of FIGS. 2A-2B . The bonded structure 300 includes at least a processor die 350, a L1 cache 304A, a L1 cache 304B, and wiring layers 324. The processor die 350 includes a substrate 310, a processor core 302A, a L2 cache 306A, a L3 cache 308, a L2 cache 306B, a processor core 302B, and wiring layers 322.

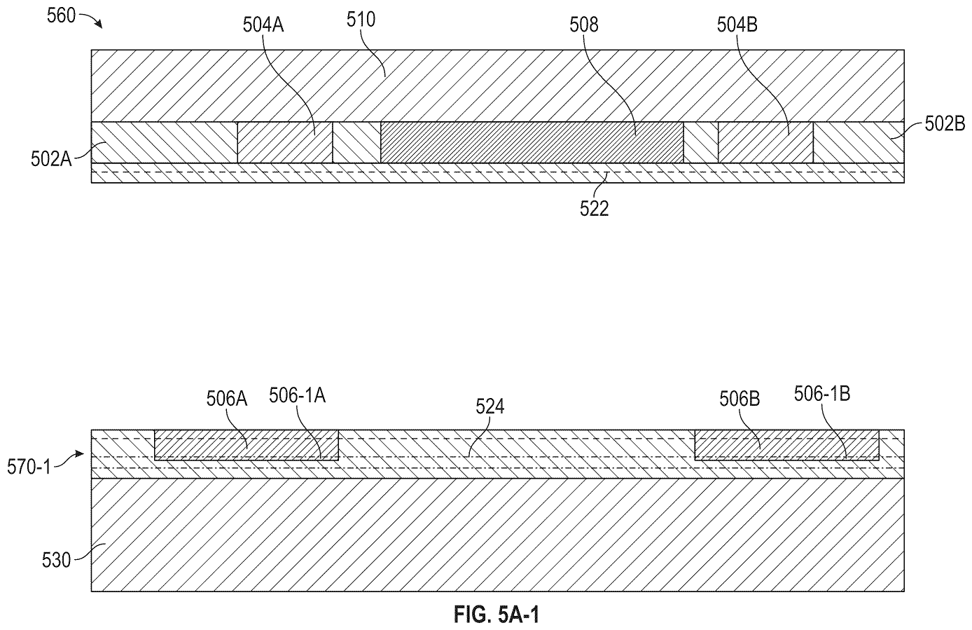

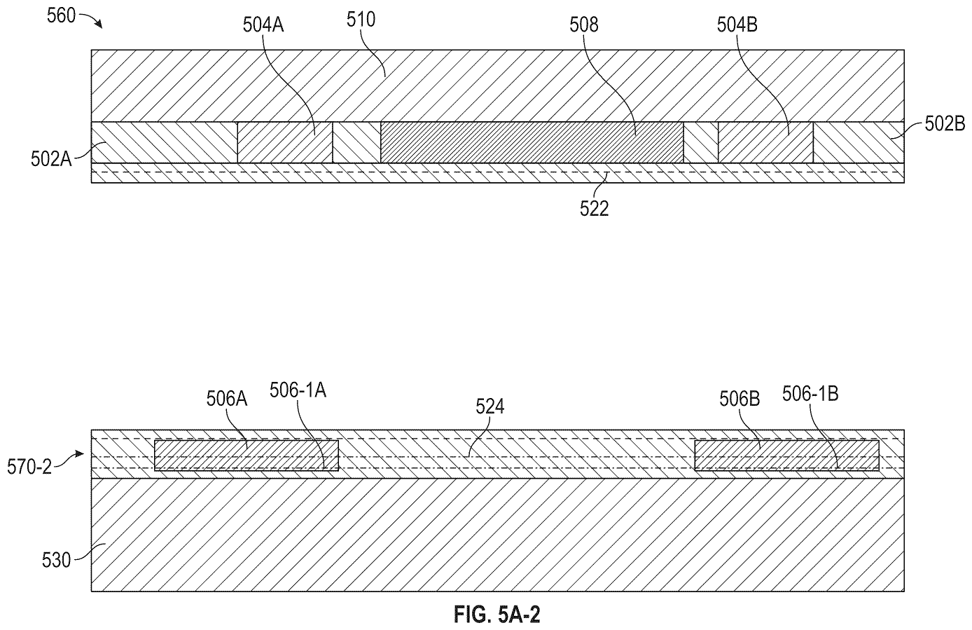

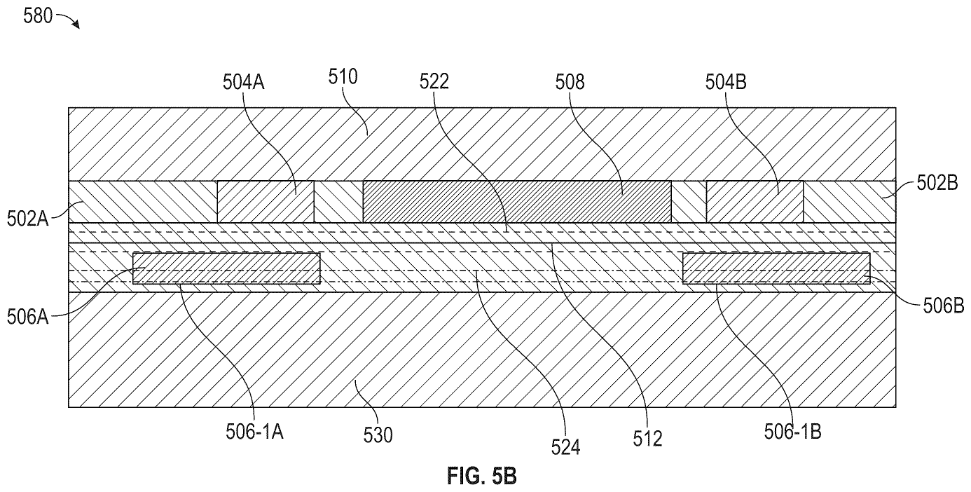

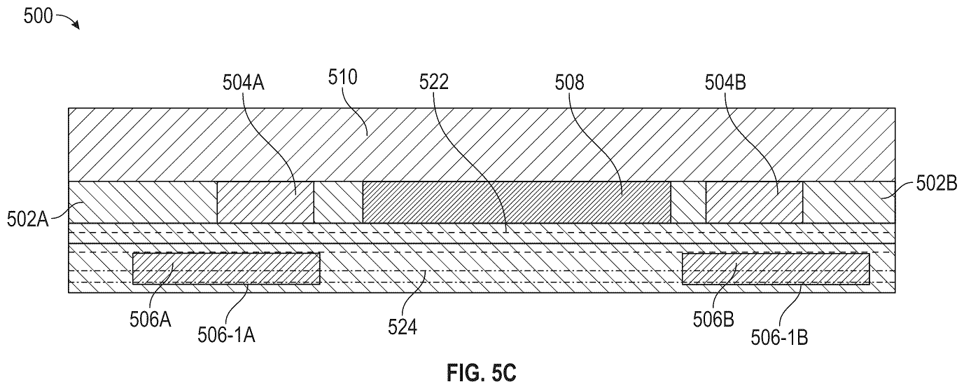

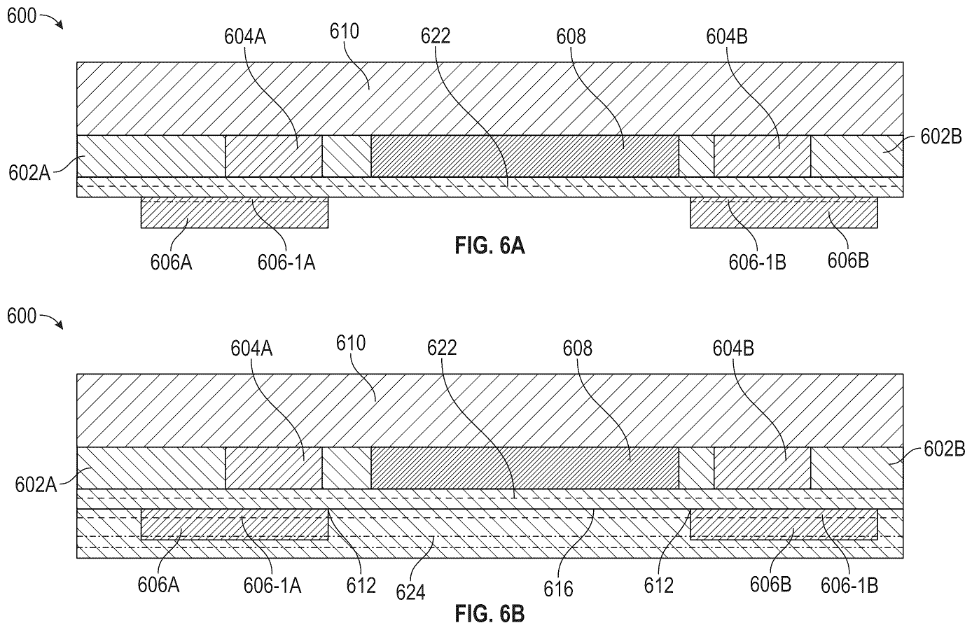

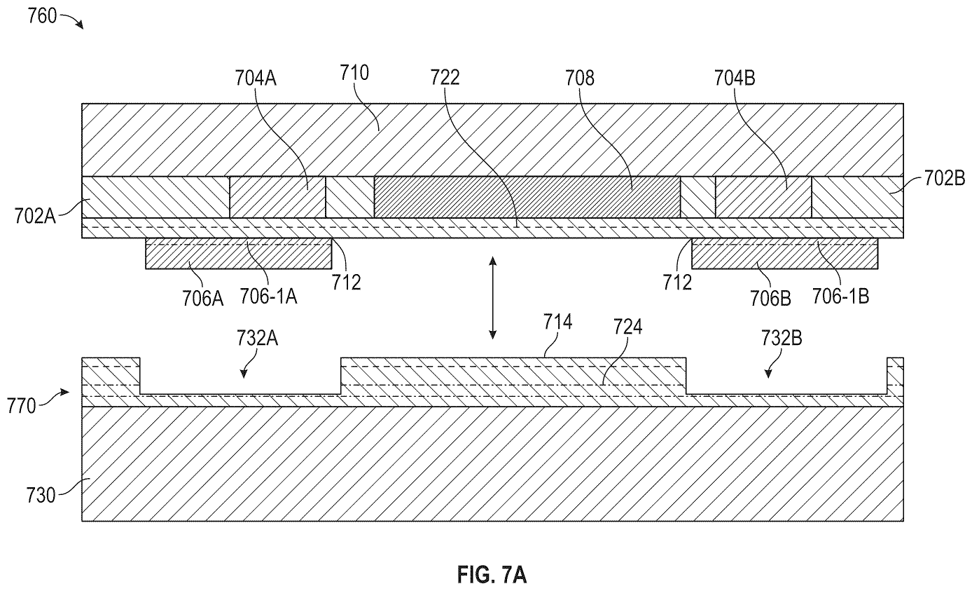

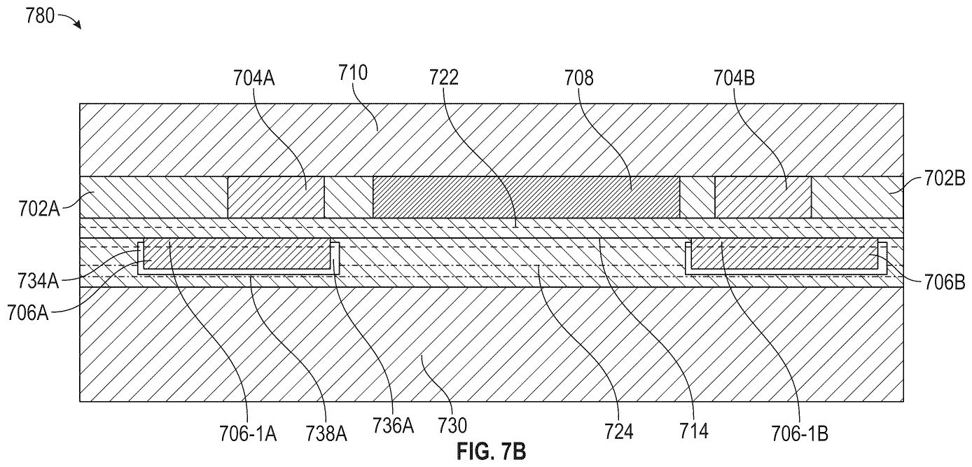

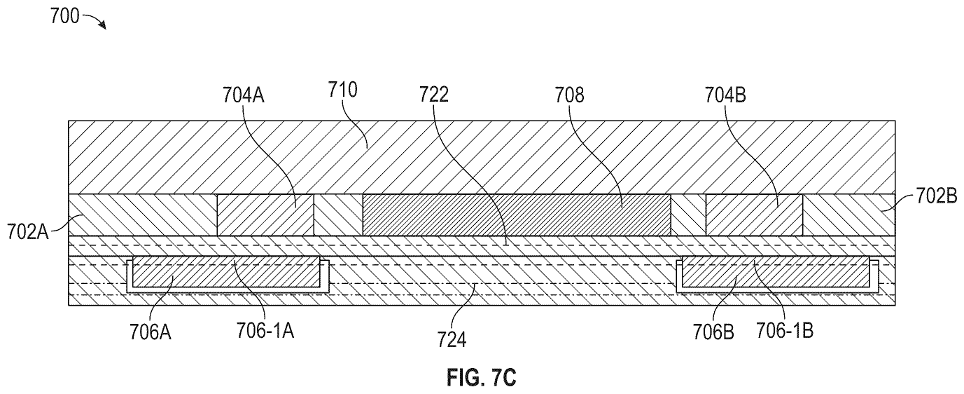

As shown in FIG. 3, the wiring layers 322 (e.g., one or more local wiring layers that include at least a hybrid bonding layer 348 for hybrid bonding the L1 cache 304A and the L1 cache 304B to the processor die 350) can be disposed vertically below the processor core 302A, the L2 cache 306A, the L3 cache 308, the L2 cache 306B, the processor core 302B. In some embodiments, L1 cache 304A is completely under the shadow of processor core 302A (i.e. without any overlap with L2 cache 306A) and L1 cache 304B is completely under the shadow of processor core 302B (i.e. without any overlap with L2 cache 306B). In some other embodiments, as shown in FIG. 3, L1 cache 304A partially overlies processor core 302A and L2 cache 306A and L1 cache 304B partially overlies processor core 302B and L2 cache 306B. The wiring layers 322 may be at least partially formed using low-k inorganic dielectric materials and/or extremely low-k (ELK) inorganic dielectric materials; i.e. at least one or more interlayer dielectrics (ILDs) of layers 322 may be using low-k or ELK inorganic dielectric material. These materials may advantageously help reduce parasitic capacitance, thereby improving signal speed and reducing power consumption and making the bonded structure 300 suitable for high-speed and/or high performance semiconductor applications. The wiring layers 322 can also laterally and/or vertically route signals as needed for the processor die 350. As shown in FIG. 3, the wiring layers can include or provide an interface 312. In some embodiments, the interface 312 can include a hybrid bonding interface (e.g., similar to a hybrid bonding interface 512 of FIG. 5B and/or a bonding interface 712 of FIG. 7A) with contact features and/or pads to enable using hybrid bonding to form the bonded structure 300. In other embodiments, the interface 312 can include a hybrid bonding interface (e.g., a hybrid bonding interface 612 of FIG. 6B) indicative of a hybrid bonding process and a deposited interface (e.g., a deposited interface 616 of FIG. 6B) indicative of a deposition process. The hybrid bonding interface can enable the L1 cache 304A and/or the L1 cache 304B to be hybrid bonded (e.g., using one or more wiring layers 304-1A of the L1 cache 304A, and/or using one or more wiring layers 304-1B of the L1 cache 304B) to the wiring layers 322. The deposited interface can indicate an artifact of a deposition process associated with the wiring layers 324 deposited under the wiring layers 322.

In some embodiments, the wiring layers 322 can be or can include one or more local wiring layers for the processor die 350. The one or more local wiring layers may be layers of the processor die 350 that are closer to processor cores 302A and 302B of the processor die 350. The one or more local wiring layers may facilitate shorter distance communication associated with the processor die 350, such as communication between the processor core 302A and the L1 cache 304A or the L2 cache 306A dedicated to the processor core 302A. The one or more local wiring layers may include metal wires that have smaller pitch and/or wire width, allowing for high-density interconnections.

The wiring layers 322 can be distinct from the wiring layers 324 that are disposed below the wiring layers 322. The L1 cache 304A and the L1 cache 304B may be at least partially embedded within the wiring layers 324. In some embodiments, the wiring layers 324 can be or can include one or more intermediate and global wiring layers for the processor die 350. The one or more intermediate and global wiring layers may facilitate longer distance communication associated with the processor die 350, such as communication between various processor cores (e.g., the processor core 302A and the processor core 302B) and/or between the processor core 302A and the L3 cache 308. Typically, global interconnects can be found nearest the surface (e.g., the front surface) of a semiconductor element, and can be connected to conductive contact features (e.g., contact pads) configured to connect to an external device (e.g., an integrated device die, a package substrate, etc.). Global interconnects can comprise one, two, three, four, or more interconnect layers. Global interconnects can be characterized by their relatively low resistance, relatively low RC time constant, and so forth. Global interconnect layers can be used for various purposes, such as for clock distribution, power distribution, long distance communications, and so forth. Local interconnects can be the bottommost interconnect layer or layers closest to the active region of an element (e.g., closest to the frontside of the element). Local interconnects can be characterized by their relatively small width, relatively tight pitch, and so forth. In some embodiments, local interconnects can be used for signal and/or power transmission across relatively small distances. For example, local interconnects may be used for local connection of transistor elements within a macro cell or sub-circuit. Intermediate interconnects can be larger than local interconnects but smaller than global interconnects. Intermediate interconnect layers can be characterized by a relatively low density of vias (for example, as compared to local interconnect layers). Intermediate interconnects may, for example, be used for communications with a large circuit block and/or between small circuit blocks. The relatively low density within intermediate interconnect layers can result in the availability of empty space. In some embodiments, circuit elements can be placed in the intermediate interconnect layers. For example, power management circuitry, mixed signal devices, passives such as capacitors, resistors, and inductors, and so forth can be included in one or more intermediate layers. In some embodiments, such circuit elements can span more than one intermediate interconnect layer. An interconnect layer (e.g., a global interconnect layer, intermediate interconnect layer, and/or local interconnect layer) can also be referred to as a metallization layer. A metallization layer can comprise an insulating material (e.g., an inorganic dielectric such as silicon oxide) with embedded conductive traces and/or vias. The interconnect layers can be connected to one another by vias that extend perpendicularly to the layers.

Compared with the one or more local wiring layers (e.g., the wiring layers 322), the one or more intermediate and global wiring layers (e.g., the wiring layers 324) may include metal wires that have larger pitch and/or wire width. Generally, local, intermediate, and global interconnect levels are based on different sets of layout rules and dimensions (e.g., minimum metal pitches, metal thickness, etc.) and may have different RC delays. For example, RC delay values can decrease from local to intermediate to global interconnect levels. The critical dimensions for different interconnect levels can vary between technology nodes. For example, a 10 nm technology node may have local interconnect levels with metal pitches of from about 35 to about 45 nm, intermediate interconnect levels with metal pitches about 50 to about 115 nm, semi-global interconnect levels with metal pitches of about 160 nm to about 180 nm, and global interconnect levels with still greater metal pitches. As another example, a 4 nm technology node may have local interconnect levels with metal pitches of about 25 to about 40 nm, intermediate interconnect levels with metal pitches of about 70 to about 80 nm, and global interconnect level with metal pitches of about 700 nm to about 750 nm. In some embodiments, local interconnect levels can have critical dimensions that require the use of extreme ultraviolet lithography, sub-lithographic patterning, or other advanced lithography techniques, while intermediate interconnect levels may use single exposure lithography. In some embodiments, where smaller RC delay interconnect levels are not accessible, the distance an interconnect may reach may be extended using, for example, buffers, restorers, and/or other circuitry at various points along a long interconnect. The term global interconnects can refer to the thickest, widest, and most separated interconnects, intermediate interconnects can refer to interconnects that are thinner and/or more densely packed than global interconnects, and local interconnects can refer to interconnects that are thinner and/or more densely packed than intermediate interconnects and global interconnects. Global interconnects can be electrically connected to intermediate interconnects, which in turn can be electrically connected to local interconnects. Local interconnects can be electrically connected to an element (e.g., to the active circuitry of an element) to provide power, ground, and/or signal connections.

For example, an average wire width associated with the wiring layers 322 may be smaller than an average wire width associated with the wiring layers 324. In some embodiments, the wiring layers 324 may be formed using materials such as silicon oxide, silicon nitride, or tetraethyl orthosilicate (TEOS). These materials may be utilized because of their insulating properties and mechanical stability, which can advantageously maintain the integrity of global interconnections (e.g., interconnections that connect different processor cores of the processor die 350) embedded in the wiring layers 324. As such, the bonded structure 300 can provide reliable performance for high-density and high-complexity semiconductor packages.

As shown in FIG. 3, the L1 cache 304A and the L1 cache 304B can be disposed vertically below the wiring layers 322. In some embodiments, the L1 cache 304A and the L1 cache 304B can be at least partially embedded within the wiring layers 324. The L1 cache 304A and the L1 cache 304B can be bonded (e.g., hybrid bonded that includes dielectric-to-dielectric direct bonds and metal-to-metal direct bonds with electrical contact or connection) to the wiring layers 322. It should be noted that, in other embodiments not illustrated in FIG. 3, the L2 cache 306A and the L1 cache 304A can be swapped (e.g., the L1 cache 304A is disposed in the processor die 350, and the L2 cache 306A is an off-chip cache hybrid bonded to the processor die 350), and/or the L2 cache 306B and the L1 cache 304B can be swapped (e.g., the L1 cache 304B is disposed in the processor die 350, and the L2 cache 306B is an off-chip cache hybrid bonded to the processor die 350).

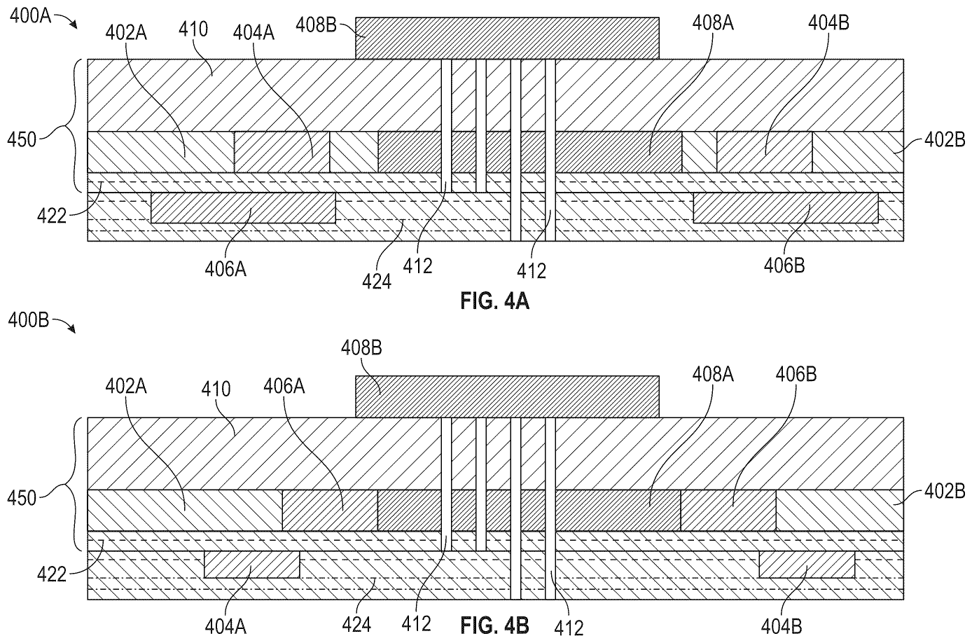

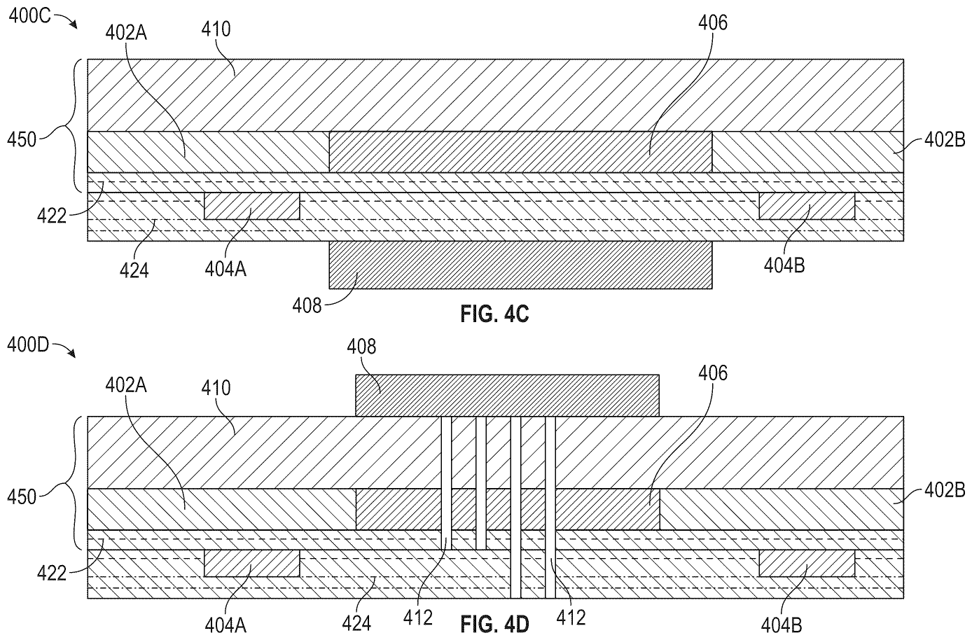

Advantageously, smaller wire widths (e.g., around or less than 200 nanometers) of wires in the wiring layers 322 (e.g., compared with wire width associated with the wiring layers 324) may facilitate hybrid bonding between the disaggregated L1 caches 304A and 304B and the processor die 350. Further, hybrid bonding the L1 cache 304A and the L1 cache 304B vertically below the processor die 350 may not hinder or negatively affect routing wires in wiring layers below processor cores 302A and 302B (e.g., the wiring layers 324) because space occupied by the off-chip L1 caches 304A and 304B may be smaller (e.g., compared with space occupied by the L3 cache 308 if the L3 cache 308 were disaggregated and disposed below the wiring layers 322). As noted above, an off-chip L3 cache (not shown in FIG. 3) can be optionally disposed vertically above the substrate 310 and processor cores 302A and 302B of the processor die 350 to further increase cache storage capacity available for the processor cores 302A and 302B. Additionally and/or optionally, a cooling semiconductor die (not shown in FIG. 3) can be also disposed above the substrate 310 to advantageously avoid thermal issues associated with the processor die 350. As will be illustrated below with reference to FIG. 4C, an off-chip L3 cache can be optionally disposed below the wiring layers 324 to increase cache storage capacity available for processor cores.

FIG. 4A illustrates a side schematic sectional view of a bonded structure 400A that includes a processor die and disaggregated caches according to some embodiments of the present disclosure. Unless otherwise noted, the components of FIG. 4A can be the same as or generally similar to like-numbered components of FIGS. 2A, 2B, and 3. The bonded structure 400A includes at least a processor die 450, a L2 cache 406A, a L2 cache 406B, a L3 cache 408B, and wiring layers 424 (e.g., one or more intermediate and global wiring layers). The processor die 450 includes a substrate 410, a processor core 402A, a L1 cache 404A, a L3 cache 408A, a L1 cache 404B, a processor core 402B, wiring layers 422 (e.g., one or more local wiring layers), and vias 412.

In contrast to the implementations of FIGS. 2A, 2B, and 3, the bonded structure 400A includes the L1 cache 404A and the L1 cache 404B that are integrated into the processor die 450 (e.g., the L1 cache 404A and the L1 cache 404B being integrated on-chip caches of the processor die 450), and includes the L2 cache 406A and the L2 cache 406B (e.g., cache chiplets hybrid bonded to corresponding portions of the processor die 450) that are disaggregated from the processor die 450 and are disposed vertically below the wiring layers 422 (e.g., one or more local wiring layers of the processor die 450). The L2 cache 406A and the L2 cache 406B can be bonded (e.g., hybrid bonded that includes dielectric-to-dielectric direct bonds and metal-to-metal direct bonds with electrical contact or connection) to the wiring layers 422.

As noted above, the vias 412 can be through-substrate vias (TSVs) that traverse vertically through the substrate 410 to provide electrical connections between components (e.g., the L3 cache 408B that can be a chiplet that is hybrid bonded to the substrate 410) on a first side of the substrate 410 and components (e.g., the processor core 402A) on or below a second side of the substrate 410 that is opposite to the first side. By further disposing the L3 cache 408B above the substrate 410 and electrically connecting the L3 cache 408B using the vias 412, the processor core 402A and/or the processor core 402B may access larger cache storage (e.g., including at least the L3 cache 408B and the L3 cache 408A) to advantageously improve computational performance associated with the bonded structure 400A. It should be noted that, rather than extending from the first side of the substrate 410 all through to the second side of the substrate 410, the vias 412 can extend from the first side of the substrate 410 to the wiring layers 422, or extend from the first side of the substrate 410 to within the wiring layers 424 in other embodiments.

As shown in FIG. 4A, the processor die 450 can access three integrated on-chip caches (e.g., the L1 cache 404A, the L1 cache 404B, the L3 cache 408A) and three chiplets or off-chip caches (e.g., the L2 cache 406A, the L2 cache 406B, and the L3 cache 408B). It should be noted that the processor die 450 can access fewer or more on-chip caches and off-chip caches than what is illustrated in FIG. 4A.

FIG. 4B illustrates a side schematic sectional view of a bonded structure 400B that includes a processor die and disaggregated caches according to some embodiments of the present disclosure. Unless otherwise noted, the components of FIG. 4B can be the same as or generally similar to like-numbered components of FIGS. 2A, 2B, 3 and 4A. The bonded structure 400B includes at least a processor die 450, a L1 cache 404A, a L1 cache 404B, a L3 cache 408B, and wiring layers 424. The processor die 450 includes a substrate 410, a processor core 402A, a L2 cache 406A, a L3 cache 408A, a L2 cache 406B, a processor core 402B, wiring layers 422, and vias 412. In some embodiments, the L1 cache 404A, the L1 cache 404B, and the L3 cache 408B are disaggregated caches or hybrid bonded chiplets that are hybrid bonded to the processor die 450. The L2 cache 406A, the L2 cache 406B, and the L3 cache 408A are on-chip caches that are integrated with or formed in the substrate 410.

As shown in FIG. 4B, in contrast to the implementation of FIG. 4A, the L1 cache 404A and the L1 cache 404B (e.g., cache chiplets or chiplets) are disaggregated from the processor die 450. Further, the L2 cache 406A and the L2 cache 408A are integrated (e.g., formed in the substrate 410) within the processor die 450.

FIG. 4C illustrates a side schematic sectional view of a bonded structure 400C that includes a processor die and disaggregated caches according to some embodiments of the present disclosure. Unless otherwise noted, the components of FIG. 4C can be the same as or generally similar to like-numbered components of FIGS. 2A, 2B, 3, 4A and 4B. The bonded structure 400C includes at least a processor die 450, a L1 cache 404A, a L1 cache 404B, a L3 cache 408, and wiring layers 424. The processor die 450 includes a substrate 410, a processor core 402A, a L2 cache 406, a processor core 402B, and wiring layers 422. In some embodiments, the L1 cache 404A and the L1 cache 404B are disaggregated caches or cache chiplets (e.g., hybrid bonded chiplets) that are hybrid bonded to the processor die 450. The L3 cache 408 is a disaggregated cache or a cache chiplet that can be hybrid bonded to the wiring layers 424. The L2 cache 406 is on-chip cache (e.g., integrated on-chip cache) that is integrated with or formed in the substrate 410.

As shown in FIG. 4C, the L2 cache 406 can be shared by the processor core 402A and the processor core 402B. The L2 cache 406 may be disposed at or near a center of the processor die 450. For example, the L2 cache 406 (e.g., integrated on chip cache) may be disposed laterally between the processor core 402A and the processor core 402B. The processor core 402A can access the L1 cache 404A through the wiring layers 422, and the L1 cache 404A can be an off-chip cache (e.g., a hybrid bonded chiplet) dedicated for the processor core 402A. The processor core 402B can access the L1 cache 404B through the wiring layers 422, and the L1 cache 404B can be an off-chip cache (e.g., a hybrid bonded chiplet) dedicated for the processor core 402B. The processor core 402A and the processor core 402B can both access the L3 cache 408 (e.g., a hybrid bonded chiplet). In other embodiments not illustrated in FIG. 4C, the L1 cache 404A and/or the L1 cache 404B can be on-chip cache for the processor die 450, and the L2 cache 406 can be an off-chip cache that is hybrid bonded to the processor die 450.

In contrast to the implementations of FIGS. 2A, 2B, 3, 4A, and 4B, the L3 cache 408 is disposed vertically below the wiring layers 422 and the wiring layers 424. In some implementations, the L3 cache 408 can be bonded (e.g., hybrid bonded that includes dielectric-to-dielectric direct bonds and metal-to-metal direct bonds with electrical contact or connection) to the wiring layers 424. Although data transfer latency between the processor cores (e.g., the processor core 402A and the processor core 402B) and the L3 cache 408 may be longer compared with data transfer latency associated with the L1 cache 404A or the L1 cache 404B due to the space occupied by the wiring layers 424, such longer data latency may not frustrate the functionality or purpose of the L3 cache 408. This is because the L3 cache 408 can afford to operate under lower speed compared with the L1 cache 404A, the L1 cache 404B, and the L2 cache 406.

FIG. 4D illustrates a side schematic sectional view of a bonded structure 400D that includes a processor die and disaggregated caches according to some embodiments of the present disclosure. Unless otherwise noted, the components of FIG. 4D can be the same as or generally similar to like-numbered components of FIGS. 2A, 2B, 3, 4A, 4B, and 4C. The bonded structure 400D includes at least a processor die 450, a L1 cache 404A, a L1 cache 404B, a L3 cache 408, and wiring layers 424. The processor die 450 includes a substrate 410, a processor core 402A, a L2 cache 406, a processor core 402B, and wiring layers 422. The substrate 410 includes the vias 412. In contrast to the implementation of FIG. 4C, the L3 cache 408 is disposed vertically above the substrate 410 rather than below the wiring layers 424 in the bonded structure 400D. In some embodiments, the L1 cache 404A and the L1 cache 404B are disaggregated caches or cache chiplets (e.g., hybrid bonded chiplets) that are hybrid bonded to the wiring layers 422. The L3 cache 408 is a disaggregated cache or a cache chiplet that can be hybrid bonded to the substrate 410. The L2 cache 406 is an on-chip cache (e.g., integrated on-chip cache) that is integrated with or formed in the substrate 410.

FIGS. 5A-1 or 5A-2, 5B, and 5C illustrate an example process for assembling a structure 500 according to some embodiments. The structure 500 can be structurally the same as or similar to at least some of the bonded structures 200A, 200B, 300, 400A, 400B, 400C, and 400D. As shown in FIG. 5A-1, a structure 560 (e.g., a processor die with wiring layers) can include a substrate 510, a processor core 502A, a L1 cache 504A, a L3 cache 508, a L1 cache 504B, a processor core 502B that are integrated with and/or formed in the substrate 510, and wiring layers 522; and a structure 570-1 can include a L2 cache 506A, a L2 cache 506B, wiring layers 524, and a carrier 530.

In some embodiments, the processor core 502A, the L1 cache 504A, the L3 cache 508, the L1 cache 504B, and the processor core 502B can be formed on or within the substrate 510 using conventional front end fabrication process, and be a part of the substrate 510. For example, the processor core 502A, the L1 cache 504A, the L3 cache 508, the L1 cache 504B, and the processor core 502B can be formed on a first side (e.g., a bottom side or active side) of the substrate 510. Afterwards, the wiring layers 522 (e.g. local and or intermediate wiring layers) can be formed on a first side (e.g., a bottom side) of the processor core 502A, the L1 cache 504A, the L3 cache 508, the L1 cache 504B, and the processor core 502B. As such, the structure 560 can be obtained or fabricated.

In some embodiments, the wiring layers 524 (e.g., intermediate and global wiring layers) can be formed or deposited on the carrier 530. The L2 cache 506A and the L2 cache 506B can be at least partially embedded within the wiring layers 524. More specifically, the carrier 530 (e.g., a substrate or a semiconductor wafer) can be prepared to provide mechanical support for the wiring layers 524 and the L2 cache 506A, L2 cache 506B. The wiring layers 524 can then be deposited onto the carrier 530. The L2 cache 506A and the L2 cache 506B (e.g., cache chiplets) can be hybrid bonded to (e.g., using one or more wiring layers 506-1A, and one or more wiring layers 506-1B) lower layers of the wiring layers 524. Then, upper layers of the wiring layers 524 can be built up to partially embed the L2 cache 506A and the L2 cache 506B to form the structure 570-1 as shown in FIG. 5A-1.

After the structure 560 and the structure 570-1 are formed as shown in FIG. 5A-1, the structure 570-1 can be bonded to the structure 560 to form a structure 580 shown in FIG. 5B. In some embodiments, the wiring layers 524, the L2 cache 506A, and/or the L2 cache 506B can be bonded (e.g., hybrid bonded that includes dielectric-to-dielectric direct bonds and metal-to-metal direct bonds with electrical contact or connection) to the wiring layers 522 to form the structure 580. Alternatively, the structure 580 shown in FIG. 5B can be formed using the structure 560 and a structure 570-2 shown in FIG. 5A-2. The structure 570-2 can be formed similar to how the structure 570-1 is formed except that the L2 cache 506A and the L2 cache 506B are fully embedded within the wiring layers 524 (e.g., intermediate and global wiring layers) in the structure 570-2. After forming the structure 570-2, the structure 580 can be formed by hybrid bonding the wiring layers 524 to the wiring layers 522.

As shown in FIG. 5B, the structure 580 includes the processor core 502A, the L1 cache 504A, the L3 cache 508, the L1 cache 504B, the processor core 502B, the substrate 510, the wiring layers 522, the wiring layers 524, the L2 cache 506A, the L2 cache 506B, and the carrier 530. As illustrated in FIG. 5B, the structure 580 can be formed by hybrid bonding the structure 560 and 570-2 through a hybrid bonding interface 512. In some embodiments, the hybrid bonding interface 512 is formed during a single hybrid bonding step and allows the wiring layers 524 and the wiring layers 522 to be hybrid bonded with each other.

FIG. 5C illustrates the structure 500 that can be formed by removing the carrier 530 from the structure 580 of FIG. 5B. As shown in FIG. 5C, the removal of the carrier 530 exposes at least the wiring layers 524. The structure 500 can be the same or similar to the bonded structure 300 except that, in the structure 500, off-chip caches are level two (L2) caches.

FIGS. 6A and 6B illustrate an example process for assembling a structure 600 according to some embodiments. The structure 600 can be structurally the same as or similar to at least some of the bonded structures 200A, 200B, 300, 400A, 400B, 400C, and 400D. As shown in FIG. 6A, the structure 600 can include a substrate 610, a processor core 602A, a L1 cache 604A, a L3 cache 608, a L1 cache 604B, a processor core 602B, wiring layers 622, a L2 cache 606A, and a L2 cache 606B. In other embodiments, the structure 600 can include fewer components that as shown here. For example, the structure 600 can include the processor core 602A and the L1 cache 604A without including any L3 cache 608.

In some embodiments, the processor core 602A, the L1 cache 604A, the L3 cache 608, the L1 cache 604B, the processor core 602B can be formed on or within the substrate 610, and can be a part of the substrate 610. For example, the processor core 602A, the L1 cache 604A, the L3 cache 608, the L1 cache 604B, and the processor core 602B can be formed on a first side (e.g., a bottom side) of the substrate 610. Afterwards, the wiring layers 622 can be formed on a first side (e.g., a bottom side) of the processor core 602A, the L1 cache 604A, the L3 cache 608, the L1 cache 604B, and the processor core 602B. Then, the chiplets L2 cache 606A and the L2 cache 606B can be bonded (e.g., hybrid bonded that includes dielectric-to-dielectric direct bonds and metal-to-metal direct bonds with electrical contact or connection without adhesive or an intervening layer or flip chipped or micro-bumped) to the wiring layers 622 using one or more wiring layers 606-1A and one or more wiring layers 606-1B to form the structure 600 as shown in FIG. 6A.

As shown in FIG. 6B, wiring layers 624 can be further formed or deposited on the wiring layers 622 to form the structure 600 as shown in FIG. 6B. After depositing the wiring layers 624, the L2 cache 606A and the L2 cache 606B can be at least partially embedded within the wiring layers 624. The structure 600 shown in FIG. 6B can be similar or the same as the structure 500 of FIG. 5C, except that there is a hybrid bonding interface 612 between the L2 cache chiplets (e.g., the L2 cache 606A and the L2 cache 606B) and the wiring layers 622, and that there is a deposited interface 616 between the wiring layers 622 and the wiring layers 624. The hybrid bonding interface 612 can enable the L2 cache chiplets (e.g., the L2 cache 606A and the L2 cache 606B) to be hybrid bonded to (e.g., using one or more wiring layers 606-1A and one or more wiring layers 606-1B) the wiring layers 622 (one or more local wiring layers). The deposited interface 616 can indicate that the wiring layers 624 (one or more intermediate and global wiring layers) is deposited under the wiring layers 622.

FIGS. 7A, 7B, and 7C illustrate an example process for assembling a structure 700 according to some embodiments. The structure 700 can be structurally the same as or similar to at least some of the bonded structures 200A, 200B, 300, 400A, 400B, 400C, and 400D. As shown in FIG. 7A, a structure 760 can include a substrate 710, a processor core 702A, a L1 cache 704A, a L3 cache 708, a L1 cache 704B, a processor core 702B, wiring layers 722, a L2 cache 706A, and a L2 cache 706B; and a structure 770 can include wiring layers 724 and a carrier 730. In some embodiments, the L2 cache 706A and the L2 cache 706B are disaggregated caches or cache chiplets (e.g., hybrid bonded chiplets) that are hybrid bonded to the wiring layers 722. The L1 cache 704A, the L1 cache 704B, and L3 cache 708 are on-chip cache (e.g., integrated cache) that are integrated with or formed in the substrate 710.

In some embodiments, the processor core 702A, the L1 cache 704A, the L3 cache 708, the L1 cache 704B, and the processor core 702B can be formed on or within the substrate 710, and be a part of the substrate 710. Afterwards, the wiring layers 722 can be formed on a first side (e.g., a bottom side) of the processor core 702A, the L1 cache 704A, the L3 cache 708, the L1 cache 704B, and the processor core 702B. The L2 cache 706A and the L2 cache 706B can be further bonded (e.g., hybrid bonded that includes dielectric-to-dielectric direct bonds and metal-to-metal direct bonds with electrical contact or connection without adhesive or an intervening layer or flip chipped or micro-bumped) to the wiring layers 722. In some embodiments, there can be a first hybrid bonding interface 712 (e.g., a hybrid bonding layer) between the L2 caches (e.g., the L2 cache 706A and the L2 cache 706B) and the wiring layers 722 using one or more wiring layers 706-1A and one or more wiring layers 706-1B.

In some embodiments, the structure 770 can be formed by depositing the wiring layers 724 to the carrier 730, and then removing portions of the wiring layers 724 for disposing and/or bonding to the L2 cache 706A and the L2 cache 706B. More specifically, after removing the portion of the wiring layers 724, the structure 770 may structurally form a cavity 732A and a cavity 732B that will be used for accommodating the L2 cache 706A and the L2 cache 706B as will be illustrated with reference to FIG. 7B.

As shown in FIG. 7B, the wiring layers 724 can be bonded to the wiring layers 722 along a second hybrid bonding interface 714 between the wiring layers 724 and the wiring layers 722. For example, the wiring layers 724 can be hybrid bonded with the wiring layers 722 along the second hybrid bonding interface 714 without adhesive or an intervening layer or flip chipped or micro-bumped. In some embodiments, after the wiring layers 724 are hybrid bonded to the wiring layers 722, the L2 cache 706A and the L2 cache 706B may be respectively accommodated within the cavity 732A and the cavity 732B with gaps between the cavities and the L2 cache chiplets (e.g. the L2 cache 706A and the L2 cache 706B). For example, there may be gaps between the L2 cache 706A and a sidewall 734A, a sidewall 736A, and a sidewall 738A of the cavity 732A.

As shown in FIG. 7C, the carrier 730 can be removed from the structure 780 to obtain the structure 700 of FIG. 7C. The structure 700 can be similar to or the same as the structure 500 of FIG. 5C.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Ser. No. 63/524,564 , filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

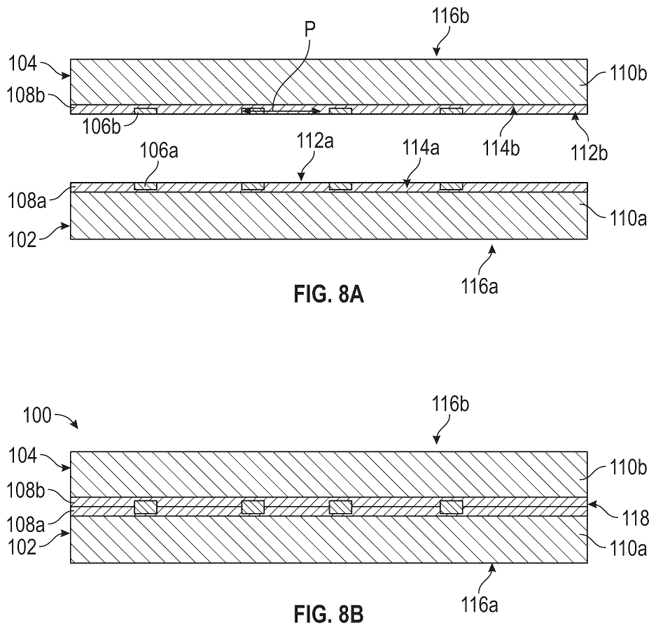

FIGS. 8A and 8B schematically illustrate cross-sectional side views of first and second elements 102, 104 prior to and after, respectively, a process for forming a directly bonded structure, and more particularly a hybrid bonded structure, according to some embodiments. In FIG. 8B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110 a and 110 b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112 a, 112 b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106 a and 106 b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 8A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, +15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A; B; C; A and B; A and C; B and C; and A, B, and C. Conjunctive language such as the phrase “at least one of X, Y and Z,” unless specifically stated otherwise, is understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded ta fair interpretation consistent with this disclosure, the principles and the novel features disclosed herein.

1. A structure comprising:
a first processor core;
first one or more wiring layers disposed vertically below the first processor core, wires of the first one or more wiring layers having a first average wire width;
second one or more wiring layers disposed vertically below the first one or more wiring layers, wires of the second one or more wiring layers having a second average wire width that is larger than the first average wire width; and
a first cache chiplet for the first processor core, the first cache chiplet disposed vertically below the first one or more wiring layers and at least partially embedded within the second one or more wiring layers,
wherein the first cache chiplet is hybrid bonded to the first one or more wiring layers.

2. The structure of claim 1, wherein the first cache chiplet and the first processor core communicate with each other through the first one or more wiring layers.

3. The structure of claim 1, wherein the first cache chiplet is a level one (L1) cache or a level two (L2) cache for the first processor core.

4. The structure of claim 1, further comprising a first on-chip cache disposed laterally to the first processor core, wherein the first on-chip cache and the first processor core form a portion of a processor die.

5. The structure of claim 4, wherein a storage capacity of the first on-chip cache is larger than a storage capacity of the first cache chiplet.

6. The structure of claim 4, wherein the first cache chiplet is an off-chip cache to the processor die.

7. The structure of claim 4, wherein the first cache chiplet is a level one (L1) cache for the first processor core, and the first on-chip cache is a level two (L2) cache for the first processor core.

8. The structure of claim 4, wherein the first cache chiplet is a level two (L2) cache for the first processor core, and the first on-chip cache is a level one (L1) cache for the first processor core.

9. The structure of claim 4, wherein the first on-chip cache and the first processor core communicate with each other through the first one or more wiring layers.

10. The structure of claim 4, wherein the processor die comprises the first on-chip cache, the first processor core, a second processor core, and a second on-chip cache, and wherein the second processor core and the second on-chip cache communicate with each other through the first one or more wiring layers.

11. (canceled)

12. (canceled)

13. (canceled)

14. (canceled)

15. (canceled)

16. (canceled)

17. (canceled)

18. (canceled)

19. (canceled)

20. (canceled)

21. A structure comprising:
a processor die that comprises a first processor core and a first on-chip cache; and
a first cache chiplet dedicated for the first processor core, the first cache chiplet disposed vertically below the first processor core and the first on-chip cache, wherein:
the first cache chiplet is hybrid bonded to the processor die; and
a storage capacity of the first cache chiplet is smaller than a storage capacity of the first on-chip cache.

22. The structure of claim 21, wherein the first on-chip cache is a level two (L2) cache for the first processor core, and the first cache chiplet is a level one (L1) cache for the first processor core.

23. The structure of claim 22, wherein the first cache chiplet is an off-chip cache to the processor die.

24. The structure of claim 21, wherein the processor die comprises a second on-chip cache, and wherein the first cache chiplet is a level one (L1) cache for the first processor core, the first on-chip cache is a level two (L2) cache for the first processor core, and the second on-chip cache is a level three (L3) cache for the first processor core.

25. The structure of claim 24, wherein the processor die comprises a substrate, and wherein the first processor core, the first on-chip cache, and the second on-chip cache are disposed vertically below the substrate.

26. (canceled)

27. (canceled)

28. (canceled)

29. (canceled)

30. (canceled)

31. A method for forming a bonded structure, the method comprising:
forming at least a processor core and an on-chip cache on a first side of a substrate;
forming first one or more wiring layers on a first side of the processor core and the on-chip cache; and
bonding a cache chiplet to a first side of the first one or more wiring layers, wherein the cache chiplet communicates with the processor core through the first one or more wiring layers as an off-chip cache that is dedicated to the processor core.

32. The method of claim 31, wherein bonding the cache chiplet to the first side of the first one or more wiring layers comprises hybrid bonding the cache chiplet to the first side of the first one or more wiring layers.

33. The method of claim 31, wherein the cache chiplet is carried by a carrier substrate.

34. The method of claim 33, wherein the cache chiplet is at least partially embedded within second one or more wiring layers that are deposited vertically above the carrier substrate.

35. The method of claim 34, further comprising removing the carrier substrate without removing the second one or more wiring layers.

36. (canceled)

37. (canceled)

38. (canceled)

39. (canceled)
